(19) United States
(12) Patent Application Publication
(10) Pub. No.: US 2026/0024604 A1
(43) Pub. Date: Jan. 22, 2026

(54) MULTIPLE FUSE COMPARISON FOR EARLY FAILURE CHECK

(71) Applicant: Micron Technology, Inc., Boise, ID (US)

(72) Inventors: Wolfgang Anton Spirkl, Germering (DE); Casto Salobrena Garcia, Munich (DE); Michael Dieter Richter, Ottobrunn (DE); Thomas Hein, München (DE); Peter Mayer, Neubiberg (DE)

(21) Appl. No.: 19/261,507

(22) Filed: Jul. 7, 2025

Related U.S. Application Data
(60) Provisional application No. 63/672,165, filed on Jul. 16, 2024.

(51) Int. Cl. G11C 29/08

(52) U.S. Cl. CPC G11C 29/08

(57) ABSTRACT

Methods, systems, and devices for multiple fuse comparison for early failure check are described. The method may include a memory system receiving signaling that indicates a first resistance level associated with one or more first fuses of a first set of fuses and receiving signaling that indicates a second resistance level associated with one or more second fuses of a second set of fuses that stores redundant data with respect to the first set of fuses. Further, the method may include generating an error flag associated with the fuse array based on a comparison of the first resistance level and the second resistance level.

### CROSS REFERENCE

The present Application for Patent claims priority to U.S. Patent Application No. 63/672,165 by Spirkl et al., entitled “MULTIPLE FUSE COMPARISON FOR EARLY FAILURE CHECK,” filed Jul. 16, 2024, which is assigned to the assignee hereof, and which is expressly incorporated by reference in its entirety herein.

### TECHNICAL FIELD

The following relates to one or more systems for memory, including multiple fuse comparison for early failure check.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports multiple fuse comparison for early failure check in accordance with examples as disclosed herein.

FIG. 2A shows an example of a system that supports multiple fuse comparison for early failure check in accordance with examples as disclosed herein.

FIG. 2B shows an example of a graph that supports multiple fuse comparison for early failure check in accordance with examples as disclosed herein.

FIG. 3 shows a block diagram of a memory system that supports multiple fuse comparison for early failure check in accordance with examples as disclosed herein.

FIG. 4 shows a flowchart illustrating a method or methods that support multiple fuse comparison for early failure check in accordance with examples as disclosed herein.

### DETAILED DESCRIPTION

A memory system may store information in a fuse array. The information stored in the fuse array may include operational information (e.g., timings, voltages) that supports functionalities of the memory system and which the memory system may read during a bootup operation. In some examples, the fuse array may include dual sets of fuses that store redundant data in some examples. During the boot up operation, the memory system may concurrently read the dual sets of fuses (e.g., using an OR function or using an AND function) and determine the operational information stored in the fuse array. However, the fuse array may be susceptible to errors which the memory system may not detect until after the bootup operation because errors in the fuse array may not affect functionality of the memory system until some condition, such as a temperature or a voltage, is reached. Thus, the memory system may function according to incorrect operational information potentially decreasing the performance of a system, including the memory system.

As described herein, a memory system may detect one or more errors in a fuse array early in operation (e.g., during the bootup operation) to ensure strong performance. To detect the errors, the memory system may compare logic values of bits stored at multiple sets of fuses. For example, during a bootup operation, the memory system may determine a first logic value of one or more bits stored at a first fuse of a first fuse set and a second logic value of one or more bits stored at a second fuse of a second fuse set, and compare the logic values. Based on the comparison, the memory system may determine if there is a difference between the logic values and if the memory system determines there is a difference, the memory system may implement one or more remedial actions, such as generating an error flag. Upon generating the error flag, the memory system may store the error flag or transmit the error flag to a host system. By detecting errors in the fuse array during the bootup operation, remedial action (e.g., memory system halting the system from completing the bootup operation) can be taken immediately (e.g., early on) thereby increasing the performance of the system.

To increase a granularity of the fuse error detection, the memory system may compare resistance values of the multiple sets of fuses. For example, during the boot operation, the memory system may measure a resistance value of the first fuse and a resistance value of the second fuse, and compare the resistance values. Based on the comparison, the memory system may determine if there is a difference between the resistance values and if the memory system determines there is a difference, the memory system may generate the error flag which may be stored at the memory system and transmitted to a host system such that the one or more remedial actions may be taken.

In addition to applicability in memory systems as described herein, techniques for multiple fuse comparison for early failure check may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by removing a defective memory device from a system of electronic device, which may improve memory access speeds, among other benefits.

Features of the disclosure are illustrated and described in the context of system. Features of the disclosure are further illustrated and described in the context of a graph and flowcharts.

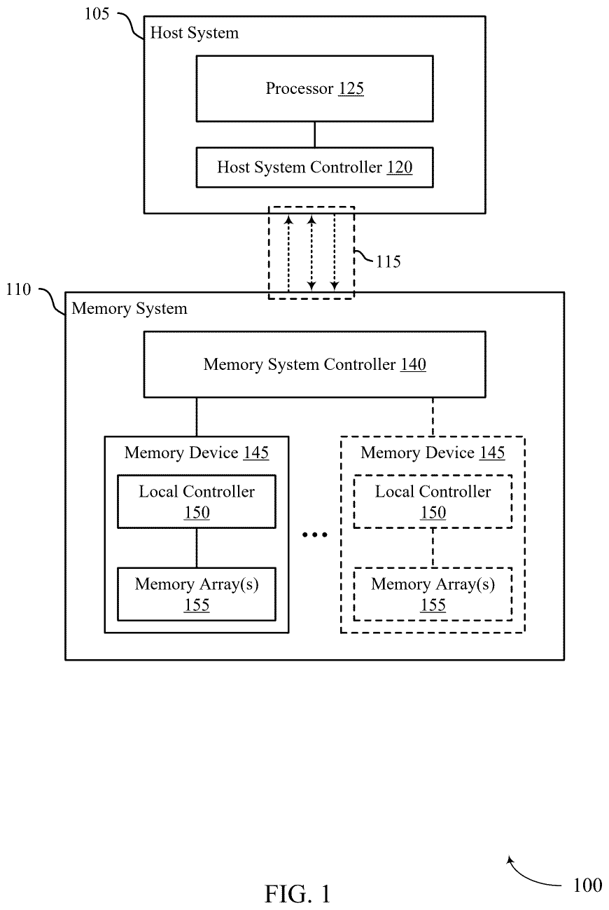

FIG. 1 illustrates an example of a system 100 that supports multiple fuse comparison for early failure check in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

As described herein, the memory system 110 (e.g., the memory system controller 140) may detect errors in a fuse array early in operation (e.g., during a bootup operation). To detect the errors, the memory system 110 may compare resistance values of the dual sets of fuses. For example, during the bootup operation, the memory system 110 may measure a resistance value of a first fuse of a first fuse set and a resistance value of a second fuse of a second fuse set and compare the resistance values. Based on the comparison, the memory system 110 may determine if there is a difference between the resistance values and if the memory system 110 determines there is a difference, the memory system 110 may generate an error flag. Upon generating the error flag, the memory system 110 may store the error flag or transmit the error flag to a host system. By detecting errors in the fuse array during the bootup operation, remedial action (e.g., memory system 110 halting the system 100 from completing the bootup operation) can be taken immediately thereby increasing the performance of the system 100.

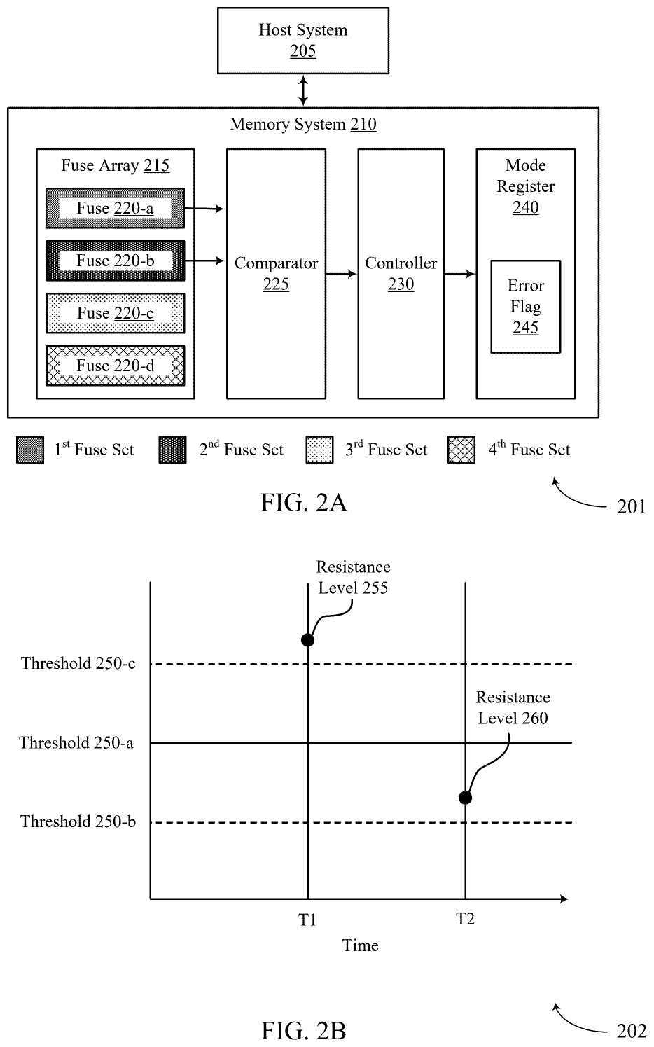

FIG. 2A shows an example of a system 201 that supports multiple fuse comparison for early failure check in accordance with examples as disclosed herein. In some examples, the system 201 may implement aspects of a system 100. For example, the system 201 may include a memory system 210 which may be an example of a memory system 110 as described with reference to FIG. 1. Further, the system 201 may include a host system 205 which may be an example of a host system 105 as described with reference to FIG. 1. FIG. 2B shows an example of a graph 202 that supports multiple fuse comparison for early failure check in accordance with examples as disclosed here. In some examples, aspects of the graph 202 may be implemented by aspects of the system 100. For example, aspects of the graph 202 may be implemented by the memory system 110 as described with reference to FIG. 1.

In some examples, the memory system 210 may include a fuse array 215 configured to store operational information for the memory system 210. For example, the fuse array 215 may store timing information and/or voltage information (among other information) that supports functionality of the memory system 210. The fuse array 215 may include multiple fuse sets (e.g., two or more fuse sets). For example, the fuse array 215 may include, at least, a first fuse set, a second fuse set, a third fuse set, and a fourth fuse set. In some examples, two or more fuse sets of the fuse array 215 may store at least some redundant operational information. For example, the first fuse set may be configured to store first data and the second fuse set may be configured to store second data that includes at least some redundant data corresponding to the first data.

As described herein, to ensure that the operational information stored in the fuse array 215 is correct (e.g., no errors such as have occurred), the memory system 210 may perform a fuse comparison operation on at least two fuse sets configured to store redundant operational information. For example, the memory system 210 may perform the fuse comparison operation on the first fuse set and the second fuse set. During the fuse comparison operation, the memory system 210 may compare a parameter (e.g., a resistance level) of one or more fuses 220 of the first fuse set to a parameter (e.g., a resistance level) of one or more fuses 220 of the second fuse set and determine whether there is an error in the operational information stored by first fuse set or the second fuse set based on the comparison.

The following describes, in more detail, the dual fuse comparison operation performed on the first fuse set and the second fuse set. In some examples, one or more components of the memory system 210 may perform the following dual fuse comparison.

At T1, a comparator 225 (e.g., an analog to digital converter (ADC)) of the memory system 210 may receive, from the fuse array 215, signaling indicating a resistance level 255 associated with a fuse 220-a of the first fuse set. Based on (e.g., in response to) the signaling, the comparator 225 may compare the resistance level 255 to a threshold 250-a and determine that the resistance level 255 satisfies (e.g., is above) the threshold 250-a. In some examples, upon determining that the resistance level 255 satisfies the threshold 250-a, the comparator 225 may set a logic value of a first bit to a first logic value (e.g., 1) and transmit, to a controller 230 of the memory system 210, signaling indicating the first bit.

Further, at T2, the comparator 225 of the memory system 210 may receive, from the fuse array 215, signaling indicating a resistance level 260 associated with a fuse 220-b of the second fuse set. In response to the signaling, the comparator 225 may compare the resistance level 260 to the threshold 250-a and determine that the resistance level 260 does not satisfy (e.g., is below) the threshold 250-a. In some examples, upon determining that the resistance level 260 does not satisfy the threshold 250-a, the comparator 225 may set a logic value of a second bit to a second logic value different than the first logic value (e.g., 0) and transmit, to the controller 230, signaling indicating the second bit.

Upon receiving the signaling from the comparator 225, the controller 230 may compare a logic value of the first bit with a logic value of the second bit to determine if there is a difference between the resistance level 255 of the fuse 220-a and the resistance level 260 of the fuse 220-b. Because the first logic value is different than the second logic value, the controller 230 may determine there is a difference between the resistance level 255 of the fuse 220-a and the resistance level 260 of the fuse 220-b. If the controller 230 determines there is a difference, the controller 230 may determine that the operational information stored by the first fuse set or the operational information stored by the second fuse set includes an error and generate an error flag 245. In some examples, the error flag 245 may indicate the error.

Additionally or alternatively, the memory system 210 may determine a magnitude of the difference between the resistance level 255 of the fuse 220-a and the resistance level 260 of the fuse 220-b. In such example, at T1, the comparator 225 may receiving signaling indicating the resistance level 255 associated with the fuse 220-a and compare the resistance level 255 to two or more thresholds 250. For example, the comparator 225 may compare the resistance level 255 to the threshold 250-a, a threshold 250-b, and a threshold 250-c. In some examples, the threshold 250-c may be larger than the threshold 250-a and the threshold 250-a may be larger than the threshold 250-b.

After comparing the resistance level 255 to the two or more thresholds 250, the comparator 225 may determine whether (e.g., that) the resistance level 255 satisfies (e.g., is above) the threshold 250-c. In some examples, upon determining that the resistance level 255 satisfies the threshold 250-c, the comparator 225 may set a logic value of a first pair of bits (e.g., two bits) to a third logic value (e.g., 11) and transmit, to the controller 230, signaling indicating the first pair of bits.

Further, at T2, the comparator 225 of the memory system 210 may receive, from the fuse array 215, signaling indicating a resistance level 260 associated with the fuse 220-b. In response to the signaling, the comparator 225 may compare the resistance level 260 to the two or more thresholds 250 and determine that the resistance level 260 satisfies (e.g., is above) the threshold 250-b, but does not satisfy (e.g., is below) the threshold 250-a and the threshold 250-c. In some examples, upon determining that the resistance level 260 satisfies the threshold 250-b, the comparator 225 may set a logic value of a second pair of bits to a fourth logic value (e.g., 01) and transmit, to the controller 230, signaling indicating the second pair of bits.

Upon receiving the signaling, the controller 230 may compare a logic value of the first pair of bits with a logic value of the second pair of bits to determine if there is a difference between the resistance level 255 of the fuse 220-a and the resistance level 260 of the fuse 220-b. Because the third logic value is different than the fourth logic value, the controller 230 may determine there is a difference between the resistance level 255 of the fuse 220-a and the resistance level 260 of the fuse 220-b.

The controller 230 may determine a magnitude of difference between the resistance level 255 of the fuse 220-a and the resistance level 260 of the fuse 220-b. In some examples, the controller 230 may determine the magnitude of difference based on the logic value of the first pair of bits and the logic value of the second pair of bits. For example, the controller 230 may determine a first magnitude of the difference between the resistance level 255 of the fuse 220-a and the resistance level 260 of the fuse 220-b if the first pair of bits are set to the third logic value (e.g., 11) and the second pair of bits if the second pair of bits are set to the fourth logic value (e.g., 01).

Alternatively, the controller 230 may determine a second magnitude of difference between the resistance level 255 of the fuse 220-a and the resistance level 260 of the fuse 220-b if the first pair of bits are set to the third logic value (e.g., 11) and the second pair of bits if the second pair of bits are set a fifth logic value (e.g., 10). In some examples, the controller 230 may set the second pair of bits to the fifth logic value if the resistance level 260 satisfies (e.g., is above) the threshold 250-a and the threshold 250-b, but does not satisfy (e.g., is below) the threshold 250-c (not shown in FIG. 2B). In such example, the second magnitude of difference may be less than the first magnitude of difference. Further, a quantity of thresholds 250 included in the two or more thresholds 250 may depend on a quantity of bits output from the comparator 225. For example, the quantity of thresholds 250 may be equal to 2ⁿ−1, where n is the quantity of bits output from the comparator 225.

In some examples, upon determining the difference between the resistance level 255 of the fuse 220-a and the resistance level 260 of the fuse 220-b, the controller 230 may determine that the operational information stored by the first fuse set or the operational information stored by the second fuse set includes the error and generate the error flag 245. In some examples, the controller 230 may generate the error flag 245 based on the magnitude of the difference. For example, the controller 230 may generate the error flag 245 if the magnitude of the difference satisfies a threshold. As an example, the controller 230 may generate the error flag 245 if the magnitude of the difference is equal to the first magnitude and may not generate the error flag 245 if the magnitude of the difference is equal to the second magnitude. In some examples, the error flag 245 may indicate the error and additionally, indicate the magnitude of the difference.

In another examples, the memory system 210 may include multiple comparators 225 and each comparator 225 may be configured to read at least a respective portion of a fuse 220. For example, the memory system 210 may include a first comparator 225 configured to receive signaling indicating a first half of a resistance level of a fuse 220 and a second comparator configured receive signaling indicating a second half of the resistance level of the fuse 220. In such example, each comparator 225 (e.g., the first comparator 225 and the second comparator 225) may compare a respective half of the resistance level to one or more thresholds and output, to the controller 230, a bit with a logic value indicative of the respective half of the resistance level for the fuse 220 resulting in a pair of bits for each fuse 220 to be compared. Similar to the methods discussed herein, the controller 230 may compare the pairs of bits output from the comparators 225 and generate the error flag 245 if the logic values of the pairs of bits do not match.

In some examples, if the controller 230 determines that there is a difference between the resistance level 255 of the fuse 220-a and the resistance level 260 of the fuse 220-b, the controller 230 may identify which resistance level (e.g., the resistance level 255 or the resistance level 260) is more likely to be correct (e.g., which fuse set is less likely to include errors). To do this, the controller 230 may read a resistance level of one or more fuses 220 included in fuse sets that are different from the first fuse set and the second fuse set. For example, the controller 230 may receive signaling indicating a resistance level for the fuse 220-c of the third fuse set. In some examples, the controller 230 may determine that the resistance level for the fuse 220-c is closer in value to the resistance level 255 of the fuse 220-a than the resistance level 260 of the fuse 220-b. In such case, the controller 230 may determine that the resistance level 255 of the fuse 220-a is more likely to be correct and may utilize the fuse 220-a for future operations. That is, the memory system 210 may read the operational information from the first fuse set as opposed to reading the operational information from the second fuse set.

Alternatively or additionally, the comparator 225 may compare the resistance level 255 and the resistance level 260 to a fixed reference value. In some examples, the fixed reference value may include an average resistance level of multiple fuses 220. For example, the fixed reference value may be the average of one or more of the resistance level 255 of the fuse 220-a, the resistance level 260 of the fuse 220-b, the resistance level of the fuse 220-c, or a resistance level of the fuse 220-d. In some examples, the controller 230 may determine that a difference between the fixed reference value and the resistance level 255 of the fuse 220-a is smaller than a difference between the fixed reference value and the resistance level 260 of the fuse 220-b. In such case, the controller 230 may determine that the resistance level 255 of the fuse 220-a is more likely to be correct and may utilize the fuse 220-a for future operations. That is, the memory system 210 may read the operational information from the first fuse set as opposed to reading the operational information from the second fuse set.

In some examples, upon generating the error flag 245, the controller 230 may store the error flag 245 in memory associated with the memory system 210. For example, as shown in FIG. 2A, the error flag 245 may be stored in a mode register 240 of the memory system 210. In order to retrieve the error flag 245, the host system 205 may periodically or aperiodically poll the mode register 240 (e.g., via a MRR command). Additionally or alternatively, the memory system 210 may transmit signaling indicating the error flag 245 to the host system 205. For example, the host system 205 may include a pin associated with the error flag 245 (e.g., an ERROR pin). When the memory system 210 detects that there is a difference between redundant fuse sets, the memory system 210 may apply a voltage to the pin that indicates that there is difference between redundant fuse sets. In response to the error flag 245, the host system 205 may suspend one or more operations or perform one or more repair operations on one or both of the fuse sets. Using the method as described herein, the memory system 210 may detect errors in the fuse array 215 early on in operation which may allow the memory system 210 perform remedial action thereby increasing the performance of the memory system 210.

Although, FIG. 2B illustrates T2 occurring subsequent to Tl in time. It should be understood that the actions performed during TI and the actions performed during T2, as describe herein, may occur during, at least, partially overlapping durations.

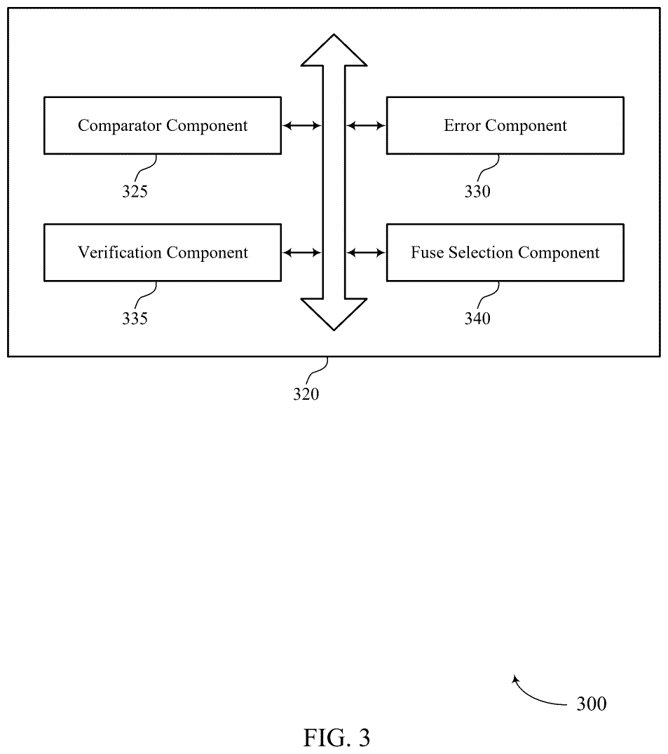

FIG. 3 shows a block diagram 300 of a memory system 320 that supports multiple fuse comparison for early failure check in accordance with examples as disclosed herein. The memory system 320 may be an example of aspects of a memory system as described with reference to FIGS. 1, 2A, and 2B. The memory system 320, or various components thereof, may be an example of means for performing various aspects of multiple fuse comparison for early failure check as described herein. For example, the memory system 320 may include a comparator component 325, an error component 330, a verification component 335, a fuse selection component 340, or any combination thereof. Each of these components, or components of subcomponents thereof (e.g., one or more processors, one or more memories), may communicate, directly or indirectly, with one another (e.g., via one or more buses).

The comparator component 325 may be configured as or otherwise support a means for receiving signaling that indicates a first resistance level associated with one or more first fuses of a first set of fuses configured to store first data. In some examples, the comparator component 325 may be configured as or otherwise support a means for receiving signaling that indicates a second resistance level associated with one or more second fuses of a second set of fuses configured to store second data including redundant data corresponding to the first data. The error component 330 may be configured as or otherwise support a means for generating an error flag based at least in part on a comparison of the first resistance level and the second resistance level.

In some examples, the error component 330 may be configured as or otherwise support a means for transmitting, to a host system, signaling indicating the error flag. In some examples, the error component 330 may be configured as or otherwise support a means for storing the error flag in memory associated with the memory system.

In some examples, the error component 330 may be configured as or otherwise support a means for determining a difference between the first resistance level and the second resistance level based at least in part on the comparison, where generating the error flag is based at least in part on determining the difference.

In some examples, to support determining the difference, the comparator component 325 may be configured as or otherwise support a means for comparing the first resistance level and the second resistance level to a threshold. In some examples, to support determining the difference, the comparator component 325 may be configured as or otherwise support a means for determining that the first resistance level satisfies the threshold and the second resistance level does not satisfy the threshold.

In some examples, the comparator component 325 may be configured as or otherwise support a means for determining a magnitude of the difference between the first resistance level and the second resistance level, where generating the error flag is based at least in part on the magnitude of the difference.

In some examples, to support determining the magnitude of the difference, the comparator component 325 may be configured as or otherwise support a means for comparing the first resistance level and the second resistance level to a plurality of thresholds. In some examples, to support determining the magnitude of the difference, the comparator component 325 may be configured as or otherwise support a means for determining that the first resistance level satisfies a first threshold of the plurality of thresholds and the second resistance level satisfies a second threshold of the plurality of thresholds.

In some examples, the error component 330 may be configured as or otherwise support a means for comparing the magnitude of the difference between the first resistance level and the second resistance level to a threshold, where generating the error flag is based at least in part on the magnitude of the difference satisfying the threshold.

In some examples, to support determining the difference, the comparator component 325 may be configured as or otherwise support a means for comparing a first portion of the first resistance level, a second portion of the first resistance level, a first portion of the second resistance level, and a second portion of the second resistance level to a threshold. In some examples, to support determining the difference, the comparator component 325 may be configured as or otherwise support a means for determining that the first portion of the first resistance level satisfies the threshold and the first portion of the second resistance level does not satisfy the threshold.

In some examples, the verification component 335 may be configured as or otherwise support a means for receiving signaling that indicates a third resistance level associated with one or more third fuses of a third set of fuses. In some examples, the fuse selection component 340 may be configured as or otherwise support a means for selecting one of the first resistance level or the second resistance level based at least in part on a comparison of the first resistance level and the second resistance level to the third resistance level.

In some examples, the verification component 335 may be configured as or otherwise support a means for comparing the first resistance level and the second resistance level to a value. In some examples, the verification component 335 may be configured as or otherwise support a means for determining a first difference between the first resistance level and the value based at least in part on the comparison. In some examples, the verification component 335 may be configured as or otherwise support a means for determining a second difference between the second resistance level and the value based at least in part on the comparison. In some examples, the fuse selection component 340 may be configured as or otherwise support a means for selecting the first resistance level based at least in part on the first difference being less than the second difference. In some examples, the value includes an average resistance level associated with two or more fuses.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

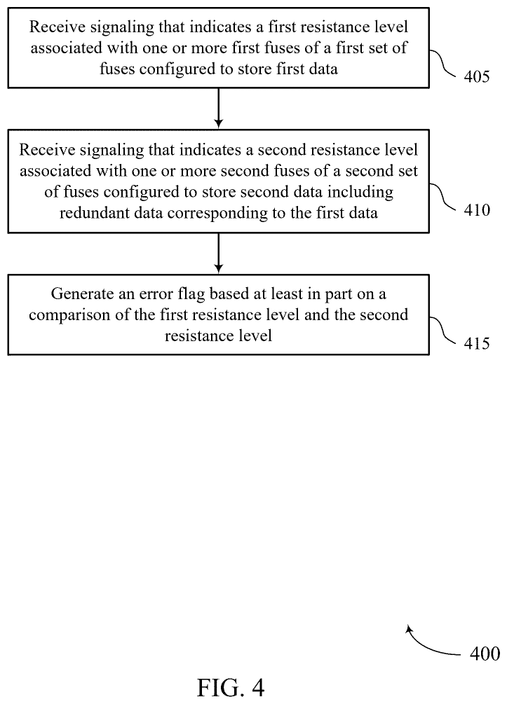

FIG. 4 shows a flowchart illustrating a method 400 that supports multiple fuse comparison for early failure check in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include receiving signaling that indicates a first resistance level associated with one or more first fuses of a first set of fuses configured to store first data. In some examples, aspects of the operations of 405 may be performed by a comparator component 325 as described with reference to FIG. 3.

At 410, the method may include receiving signaling that indicates a second resistance level associated with one or more second fuses of a second set of fuses configured to store second data including redundant data corresponding to the first data. In some examples, aspects of the operations of 410 may be performed by a comparator component 325 as described with reference to FIG. 3.

At 415, the method may include generating an error flag based at least in part on a comparison of the first resistance level and the second resistance level. In some examples, aspects of the operations of 415 may be performed by an error component 330 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving signaling that indicates a first resistance level associated with one or more first fuses of a first set of fuses configured to store first data; receiving signaling that indicates a second resistance level associated with one or more second fuses of a second set of fuses configured to store second data including redundant data corresponding to the first data; and generating an error flag based at least in part on a comparison of the first resistance level and the second resistance level.

Aspect 2: The method, apparatus, or non-transitory computer-readable medium of aspect 1, further including operations, features, circuitry, logic, means, or instructions, or any combination thereof for transmitting, to a host system, signaling indicating the error flag.

Aspect 3: The method, apparatus, or non-transitory computer-readable medium of any of aspects 1 through 2, further including operations, features, circuitry, logic, means, or instructions, or any combination thereof for storing the error flag in memory associated with the memory system.

Aspect 4: The method, apparatus, or non-transitory computer-readable medium of any of aspects 1 through 3, further including operations, features, circuitry, logic, means, or instructions, or any combination thereof for determining a difference between the first resistance level and the second resistance level based at least in part on the comparison, where generating the error flag is based at least in part on determining the difference.

Aspect 5: The method, apparatus, or non-transitory computer-readable medium of aspect 4, where determining the difference includes operations, features, circuitry, logic, means, or instructions, or any combination thereof for comparing the first resistance level and the second resistance level to a threshold and determining that the first resistance level satisfies the threshold and the second resistance level does not satisfy the threshold.

Aspect 6: The method, apparatus, or non-transitory computer-readable medium of any of aspects 4 through 5, further including operations, features, circuitry, logic, means, or instructions, or any combination thereof for determining a magnitude of the difference between the first resistance level and the second resistance level, where generating the error flag is based at least in part on the magnitude of the difference.

Aspect 7: The method, apparatus, or non-transitory computer-readable medium of aspect 6, where determining the magnitude of the difference includes operations, features, circuitry, logic, means, or instructions, or any combination thereof for comparing the first resistance level and the second resistance level to a plurality of thresholds and determining that the first resistance level satisfies a first threshold of the plurality of thresholds and the second resistance level satisfies a second threshold of the plurality of thresholds.

Aspect 8: The method, apparatus, or non-transitory computer-readable medium of any of aspects 6 through 7, further including operations, features, circuitry, logic, means, or instructions, or any combination thereof for comparing the magnitude of the difference between the first resistance level and the second resistance level to a threshold, where generating the error flag is based at least in part on the magnitude of the difference satisfying the threshold.

Aspect 9: The method, apparatus, or non-transitory computer-readable medium of any of aspects 4 through 8, where determining the difference includes operations, features, circuitry, logic, means, or instructions, or any combination thereof for comparing a first portion of the first resistance level, a second portion of the first resistance level, a first portion of the second resistance level, and a second portion of the second resistance level to a threshold and determining that the first portion of the first resistance level satisfies the threshold and the first portion of the second resistance level does not satisfy the threshold.

Aspect 10: The method, apparatus, or non-transitory computer-readable medium of any of aspects 1 through 9, further including operations, features, circuitry, logic, means, or instructions, or any combination thereof for receiving signaling that indicates a third resistance level associated with one or more third fuses of a third set of fuses and selecting one of the first resistance level or the second resistance level based at least in part on a comparison of the first resistance level and the second resistance level to the third resistance level.

Aspect 11: The method, apparatus, or non-transitory computer-readable medium of any of aspects 1 through 10, further including operations, features, circuitry, logic, means, or instructions, or any combination thereof for comparing the first resistance level and the second resistance level to a value; determining a first difference between the first resistance level and the value based at least in part on the comparison; determining a second difference between the second resistance level and the value based at least in part on the comparison; and selecting the first resistance level based at least in part on the first difference being less than the second difference.

Aspect 12: The method, apparatus, or non-transitory computer-readable medium of aspect 11, where the value includes an average resistance level associated with two or more fuses.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 13: A memory system, including: a fuse array including a first set of fuses configured to store first data and a second set of fuses configured to store second data, the second data including redundant data corresponding to the first data; and one or more controllers coupled with the fuse array and configured to cause the memory system to: receive signaling that indicates a first resistance level associated with one or more first fuses of the first set of fuses; receive signaling that indicates a second resistance level associated with one or more second fuses of the second set of fuses; and generate an error flag associated with the fuse array based at least in part on a comparison of the first resistance level and the second resistance level.

Aspect 14: The memory system of aspect 13, where the one or more controllers are further configured to cause the memory system to: transmit, to a host system, signaling indicating the error flag.

Aspect 15: The memory system of any of aspects 13 through 14, where the one or more controllers are further configured to cause the memory system to: store the error flag in memory associated with the memory system.

Aspect 16: The memory system of any of aspects 13 through 15, where the one or more controllers are further configured to cause the memory system to: determine a difference between the first resistance level and the second resistance level based at least in part on the comparison, where the one or more controllers are configured to cause the memory system to generate the error flag based at least in part on determining the difference.

Aspect 17: The memory system of aspect 16, where, to determine the difference, the one or more controllers are configured to cause the memory system to: compare the first resistance level and the second resistance level to a threshold; and determine that the first resistance level satisfies the threshold and the second resistance level does not satisfy the threshold.

Aspect 18: The memory system of any of aspects 16 through 17, where the one or more controllers are further configured to cause the memory system to: determine a magnitude of the difference between the first resistance level and the second resistance level, where the one or more controllers are configured to cause the memory system to generate the error flag based at least in part on the magnitude of the difference.

Aspect 19: The memory system of aspect 18, where, to determine the magnitude of the difference, the one or more controllers are configured to cause the memory system to: compare the first resistance level and the second resistance level to a plurality of thresholds; and determine that the first resistance level satisfies a first threshold of the plurality of thresholds and the second resistance level satisfies a second threshold of the plurality of thresholds.

Aspect 20: The memory system of any of aspects 18 through 19, where the one or more controllers are further configured to cause the memory system to: compare the magnitude of the difference between the first resistance level and the second resistance level to a threshold, where the one or more controllers are configured to generate the error flag based at least in part on the magnitude of the difference satisfying the threshold.

Aspect 21: The memory system of any of aspects 16 through 20, to determine the difference, the one or more controllers are configured to cause the memory system to: compare a first portion of the first resistance level, a second portion of the first resistance level, a first portion of the second resistance level, and a second portion of the second resistance level to a threshold; and determine that the first portion of the first resistance level satisfies the threshold and the first portion of the second resistance level does not satisfy the threshold.

Aspect 22: The memory system of any of aspects 13 through 21, where the one or more controllers are further configured to cause the memory system to: receive signaling that indicates a third resistance level associated with one or more third fuses of a third set of fuses; and select one of the first resistance level or the second resistance level based at least in part on a comparison of the first resistance level and the second resistance level to the third resistance level.

Aspect 23: The memory system of any of aspects 13 through 22, where the one or more controllers are further configured to cause the memory system to: compare the first resistance level and the second resistance level to a value; determine a first difference between the first resistance level and the value based at least in part on the comparison; determine a second difference between the second resistance level and the value based at least in part on the comparison; and select the first resistance level based at least in part on the first difference being less than the second difference.

Aspect 24: The memory system of aspect 23, where the value includes an average resistance level associated with two or more fuses included in the fuse array.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a fuse array comprising a first set of fuses configured to store first data and a second set of fuses configured to store second data, the second data comprising redundant data corresponding to the first data; and
one or more controllers coupled with the fuse array and configured to cause the memory system to:
receive signaling that indicates a first resistance level associated with one or more first fuses of the first set of fuses;
receive signaling that indicates a second resistance level associated with one or more second fuses of the second set of fuses; and
generate an error flag associated with the fuse array based at least in part on a comparison of the first resistance level and the second resistance level.

2. The memory system of claim 1, wherein the one or more controllers are further configured to cause the memory system to:
transmit, to a host system, signaling indicating the error flag.

3. The memory system of claim 1, wherein the one or more controllers are further configured to cause the memory system to:
store the error flag in memory associated with the memory system.

4. The memory system of claim 1, wherein the one or more controllers are further configured to cause the memory system to:
determine a difference between the first resistance level and the second resistance level based at least in part on the comparison, wherein the one or more controllers are configured to cause the memory system to generate the error flag based at least in part on determining the difference.

5. The memory system of claim 4, wherein, to determine the difference, the one or more controllers are configured to cause the memory system to:
compare the first resistance level and the second resistance level to a threshold; and
determine that the first resistance level satisfies the threshold and the second resistance level does not satisfy the threshold.

6. The memory system of claim 4, wherein the one or more controllers are further configured to cause the memory system to:
determine a magnitude of the difference between the first resistance level and the second resistance level, wherein the one or more controllers are configured to cause the memory system to generate the error flag based at least in part on the magnitude of the difference.

7. The memory system of claim 6, wherein, to determine the magnitude of the difference, the one or more controllers are configured to cause the memory system to:
compare the first resistance level and the second resistance level to a plurality of thresholds; and
determine that the first resistance level satisfies a first threshold of the plurality of thresholds and the second resistance level satisfies a second threshold of the plurality of thresholds.

8. The memory system of claim 6, wherein the one or more controllers are further configured to cause the memory system to:
compare the magnitude of the difference between the first resistance level and the second resistance level to a threshold, wherein the one or more controllers are configured to generate the error flag based at least in part on the magnitude of the difference satisfying the threshold.

9. The memory system of claim 4, to determine the difference, the one or more controllers are configured to cause the memory system to:
compare a first portion of the first resistance level, a second portion of the first resistance level, a first portion of the second resistance level, and a second portion of the second resistance level to a threshold; and
determine that the first portion of the first resistance level satisfies the threshold and the first portion of the second resistance level does not satisfy the threshold.

10. The memory system of claim 1, wherein the one or more controllers are further configured to cause the memory system to:
receive signaling that indicates a third resistance level associated with one or more third fuses of a third set of fuses; and
select one of the first resistance level or the second resistance level based at least in part on a comparison of the first resistance level and the second resistance level to the third resistance level.

11. The memory system of claim 1, wherein the one or more controllers are further configured to cause the memory system to:
compare the first resistance level and the second resistance level to a value;
determine a first difference between the first resistance level and the value based at least in part on the comparison;
determine a second difference between the second resistance level and the value based at least in part on the comparison; and
select the first resistance level based at least in part on the first difference being less than the second difference.

12. The memory system of claim 11, wherein the value comprises an average resistance level associated with two or more fuses included in the fuse array.

13. A method by a memory system, comprising:
receiving signaling that indicates a first resistance level associated with one or more first fuses of a first set of fuses configured to store first data;
receiving signaling that indicates a second resistance level associated with one or more second fuses of a second set of fuses configured to store second data comprising redundant data corresponding to the first data; and
generating an error flag based at least in part on a comparison of the first resistance level and the second resistance level.

14. The method of claim 13, further comprising:
transmitting, to a host system, signaling indicating the error flag.

15. The method of claim 13, further comprising:
storing the error flag in memory associated with the memory system.

16. The method of claim 13, further comprising:
determining a difference between the first resistance level and the second resistance level based at least in part on the comparison, wherein generating the error flag is based at least in part on determining the difference.

17. The method of claim 13, further comprising:
receiving signaling that indicates a third resistance level associated with one or more third fuses of a third set of fuses; and
selecting one of the first resistance level or the second resistance level based at least in part on a comparison of the first resistance level and the second resistance level to the third resistance level.

18. The method of claim 13, further comprising:
comparing the first resistance level and the second resistance level to a value;
determining a first difference between the first resistance level and the value based at least in part on the comparison;
determining a second difference between the second resistance level and the value based at least in part on the comparison; and
selecting the first resistance level based at least in part on the first difference being less than the second difference.

19. A non-transitory computer-readable medium storing code, the code comprising instructions executable by one or more processors to:
receive signaling that indicates a first resistance level associated with one or more first fuses of a first set of fuses configured to store first data;
receive signaling that indicates a second resistance level associated with one or more second fuses of a second set of fuses configured to store second data comprising redundant data corresponding to the first data; and
generate an error flag based at least in part on a comparison of the first resistance level and the second resistance level.

20. The non-transitory computer-readable medium of claim 19, wherein the instructions are further executable by the one or more processors to:
transmit, to a host system, signaling indicating the error flag.

21. The non-transitory computer-readable medium of claim 19, wherein the instructions are further executable by the one or more processors to:
store the error flag in memory.

22. The non-transitory computer-readable medium of claim 19, wherein the instructions are further executable by the one or more processors to:
determine a difference between the first resistance level and the second resistance level based at least in part on the comparison, wherein generating the error flag is based at least in part on determining the difference.
